(19) United States
(12) Patent Application Publication
(10) Pub. No.: US 2020/0273953 A1
(43) Pub. Date: Aug. 27, 2020

(54) METHODS OF FORMING SHORT-CHANNEL AND LONG-CHANNEL TRANSISTOR DEVICES WITH DIFFERENT HEIGHTS OF WORK FUNCTION METAL AND THE RESULTING IC PRODUCTS

(71) Applicant: GLOBALFOUNDRIES Inc., Grand Cayman (KY)

(72) Inventors: Tao Chu, Clifton Park, NY (US); Wei Ma, Clifton Park, NY (US); Jae Gon Lee, Waterford, NY (US); Hong Yu, Clifton Park, NY (US); Zhenyu Hu, Clifton Park, NY (US); Srikanth Balaji Samavedam, Cohoes, NY (US)

(21) Appl. No.: 16/287,365

(22) Filed: Feb. 27, 2019

(51) Int. Cl. H01L 29/10; H01L 29/417; H01L 29/66; H01L 29/78; H01L 27/092

(52) U.S. Cl. CPC H01L 29/1037; H01L 29/41791; H01L 27/0924; H01L 29/785; H01L 29/66795

(57) ABSTRACT

One illustrative integrated circuit product disclosed herein includes a short-channel transistor device and a long-channel transistor device formed above a semiconductor substrate, wherein a first gate structure for the short-channel transistor device includes a short-channel WFM layer with a first upper surface that is positioned at a first distance above an upper surface of the semiconductor substrate, and wherein a second gate structure for the long-channel transistor device includes a long-channel WFM layer with a second upper surface that is positioned at a second distance above the upper surface of the semiconductor substrate, wherein the first distance is greater than the second distance.

### BACKGROUND

Generally, the present disclosure relates to the manufacture of semiconductor devices, and, more specifically, to various novel methods of forming short-channel and long-channel transistor devices with different heights of work function metal and the resulting integrated circuit (IC) products.

In modern integrated circuits, such as microprocessors, storage devices and the like, a very large number of circuit elements, especially transistors, are provided on a restricted chip area. Transistors come in a variety of shapes and forms, e.g., planar transistors, FinFET transistors, nanowire devices, etc. The transistors are typically either NMOS (NFET) or PMOS (PFET) type devices wherein the “N” and “P” designation is based upon the type of dopants used to create the source/drain regions of the devices.

Some transistor devices are manufactured with relatively shorter gate lengths, e.g., 20 nm or less based upon current-day technology, and such devices may be generally referred to as short-channel devices. Other transistor devices are manufactured with relatively longer gate lengths, e.g., greater than 20 nm (and sometimes much greater) based upon current-day technology, and such devices may be generally referred to as long-channel devices. In general, short-channel devices exhibit faster switching speeds than long-channel devices. Additionally, short-channel devices exhibit larger off-state leakage currents than do long-channel devices. Short-channel devices are typically employed in circuits where high speed performance is necessary, e.g., logic circuits. On the other hand, long-channel devices may be employed in circuits where it is important to reduce power consumption and long-channel devices may also be employed in peripheral circuitry, such as input/output circuitry.

The gate structures for both short-channel devices and long-channel devices may be manufactured using known replacement gate manufacturing techniques. In general, the replacement gate manufacturing technique involves removing a previously formed sacrificial gate structure to define a replacement gate cavity positioned between a sidewall spacer structure that was formed adjacent the sacrificial gate structures. At that point, a plurality of conformal deposition processes are performed to form a plurality of conformal layers of gate materials within the replacement gate cavity. These conformal layers of material typically include a high-k gate insulation layer, a work-function adjusting metal (WFM) layer and one or more additional metal-containing layers. Any unfilled portion of the replacement gate cavity may be eventually filled with a bulk conductive material, such as tungsten. At some point during the process flow, the materials for the replacement gate within the replacement gate cavity will be recessed to make room for a final gate cap structure that will be positioned over the final replacement gate structure. The net result of such replacement gate manufacturing techniques is that the vertical height of the WFM layer along the sidewall spacer structure is typically the same for both short-channel devices and long-channel devices.

In designing IC products, various design or target parameters for the finished IC product are established by the ultimate purchaser of the IC product, and these design parameters are typically established very early in the design process. IC products may also be designed using a library of virtual standard cells that perform basic Boolean operations, such as a NAND gate or a NOR gate. Moreover, these libraries may be based in different categories of transistor devices that have differing operational characteristics. For example, some of the libraries may be based upon cells having transistors that exhibit a low threshold voltage (LVT devices or cells), a regular threshold voltage (RVT devices or cells) or a high threshold voltage (HVT devices or cells). In relative terms, LVT devices operate at faster switching speeds and exhibit greater off-state leakage currents as compared to the HVT devices. The performance of the RVT devices may exhibit speed and leakage current characteristics somewhere between those of the LVT devices and HVT devices. Circuit designers may employ LVT, RVT and HVT devices in any particular application. Typically, the overall product specification may set a targeted ring oscillator frequency for the particular circuit under consideration. At some point during the design process, the circuit was initially designed with LVT library cells (that exhibit the fastest switching speeds and the greatest leakage currents) and this initial LVT-based circuit design exhibits a cycle time that is less than the targeted ring oscillator frequency for the circuit. At that point, the circuit designer may undertake various actions to optimize the performance of the circuit while still meeting all of the target specifications for the product. For example, the circuit designer may try to replace one or more of the LVT cell portions of the initial circuit with HVT cell elements so as to reduce the overall leakage currents from the circuit. If this revised circuit design has a cycle time that is still less than the targeted ring oscillator frequency, the HVT cell element may be substituted for the LVT cell element so as to enhance the performance of the overall circuit in terms of reduced leakage currents. This process is repeated as needed to produce the most optimal design of the circuit in terms of operational speed and reduced leakage currents.

In some applications, both short-channel devices and long-channel devices may be initially fabricated such that they exhibit certain characteristics, e.g., threshold voltage, leakage currents, etc., and the characteristic of these initially fabricated transistor devices may make the IC product exhibit operational characteristics that do not meet the target parameters and specification established by the product purchaser. As a result, IC product manufacturers may undertake various activities in an attempt to try to modify or “tune” one or more of the performance characteristics of the initially-manufactured transistors such that the final IC product meets the target specifications set by the purchaser of the final IC product. One of these techniques may involve the implantation of various dopant atoms into the channel region of the short-channel and/or long-channel devices on the product. Unfortunately, while the implanting of such dopant materials may have positive effects with respect to some operational aspects of the transistor device, e.g., increased operational speed, there may also be some detrimental effects to the performance of the transistor devices (and the overall circuity), e.g., greater leakage currents, due to the presence of the performance-modifying implanted dopant materials within the channel region of one or both of the short-channel and long-channel transistor devices.

The present disclosure is directed to various methods of forming short-channel and long-channel transistor devices with different heights of work function metal and the resulting IC products that may solve or reduce one or more of the problems identified above.

### SUMMARY

The following presents a simplified summary of at least one disclosed embodiment in order to provide a basic understanding of some aspects of the subject matter disclosed herein. This summary is not an exhaustive overview of all of the subject matter disclosed herein. It is not intended to identify key or critical elements of the subject matter disclosed herein or to delineate the scope of any claims directed to any of the subject matter disclosed herein. Its sole purpose is to present some concepts in a simplified form as a prelude to the more detailed description that is discussed later in the application.

Generally, the present disclosure is directed to various novel methods of forming short-channel and long-channel transistor devices with different heights of work function metal and the resulting IC products. One illustrative integrated circuit product disclosed herein includes a short-channel transistor device and a long-channel transistor device formed above a semiconductor substrate, wherein a first gate structure for the short-channel transistor device includes a short-channel WFM layer with a first upper surface that is positioned at a first distance above an upper surface of the semiconductor substrate, and wherein a second gate structure for the long-channel transistor device includes a long-channel WFM layer with a second upper surface that is positioned at a second distance above the upper surface of the semiconductor substrate, wherein the first distance is greater than the second distance.

One illustrative method disclosed herein includes forming first and second sacrificial gate structures, respectively, for a short-channel transistor device and a long-channel transistor device, removing the first and second sacrificial gate structures to form first and second replacement gate cavities, respectively, for the short-channel transistor device and the long-channel transistor device, and forming a conformal work-function adjusting metal layer (conformal WFM layer) in the first and second replacement gate cavities. In this example, the method also includes performing at least one process operation to remove portions of the conformal WFM layer from within the first and second replacement gate cavities to form a short-channel WFM layer for a first final gate structure of the short-channel transistor device and a long-channel WFM layer for a second final gate structure for the long-channel transistor device, wherein a first upper surface of the short-channel WFM layer is positioned at a first distance above an upper surface of the semiconductor substrate and wherein a second upper surface of the long-channel WFM layer is positioned at a second distance above the upper surface of the semiconductor substrate, wherein the first distance is greater than the second distance.

### BRIEF DESCRIPTION OF THE DRAWINGS

The disclosure may be understood by reference to the following description taken in conjunction with the accompanying drawings, in which like reference numerals identify like elements, and in which:

FIGS. 1-22 depict various illustrative novel methods disclosed herein for forming short-channel and long-channel transistor devices with different heights of work function metal and the resulting IC products.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase. As will be readily apparent to those skilled in the art upon a complete reading of the present application, the methods disclosed herein may be employed in manufacturing a variety of different devices, including, but not limited to, logic devices, memory devices, etc., and the devices may be may be either NMOS or PMOS devices.

As will be appreciated by those skilled in the art after a complete reading of the present application, various doped regions, e.g., source/drain regions, halo implant regions, well regions and the like, are not depicted in the attached drawings. Of course, the inventions disclosed herein should not be considered to be limited to the illustrative examples depicted and described herein. The various components and structures of the integrated circuit devices 100 disclosed herein may be formed using a variety of different materials and by performing a variety of known techniques, e.g., a chemical vapor deposition (CVD) process, an atomic layer deposition (ALD) process, a thermal growth process, spin-coating techniques, etc. The thicknesses of these various layers of material may also vary depending upon the particular application. With reference to the attached figures, various illustrative embodiments of the methods and devices disclosed herein will now be described in more detail.

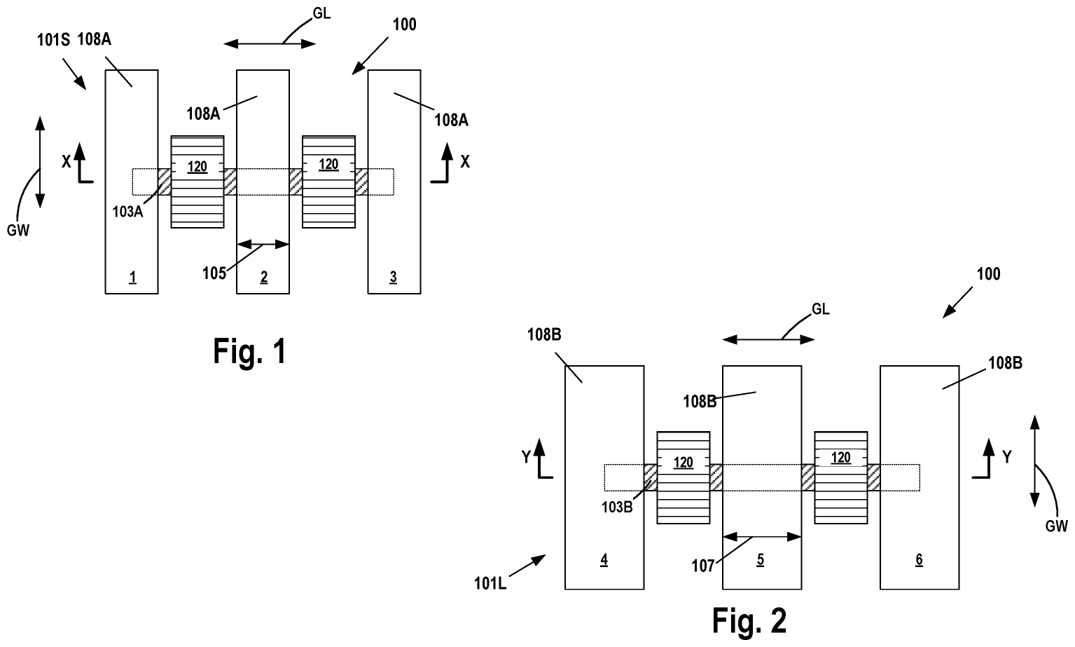

FIGS. 1-22 depict various illustrative novel methods disclosed herein for forming short-channel and long-channel transistor devices with different heights of work-function adjusting metal layers in their gate structures and the resulting IC products 100. In the illustrative examples depicted herein, the transistors are FinFET devices. However, as will be appreciated by those skilled in the art after a complete reading of the present application, the methods disclosed herein may be applied to forming other types of transistor devices, such as, for example, planar transistor devices.

FIGS. 1 and 2 are simplistically depicted plan views of an IC product 100 comprised of a short-channel transistor 101S having a channel (or gate) length 105 and a long-channel transistor 101L having a channel (or gate) length 107, wherein the gate length 107 is intentionally greater than the gate length 105. That is, the gate lengths 105, 107 are specifically and intentionally manufactured to be significantly different, and the gate lengths 105, 107 are not merely the result of manufacturing tolerances. In one illustrative example, based upon current day technology, the gate length 105 may be about 20 nm or less, while the gate length 107 may be greater than 20 nm, and in some cases significantly larger than 20 nm, e.g., 60-200 nm. Of course, the above-referenced exemplary absolute numbers are provided by way of example only as the physical size of the gate lengths 105, 107 may vary as technological advances are made and/or depending upon the particular application for the IC product 100. The transistors 101S, 101L may be NFET transistors or they may be PFET transistors.

As noted above, in the illustrative examples depicted herein, the short-channel transistor 101S and the long-channel transistor 101L are FinFET devices. FIG. 1 is a simplistic plan view of portions of the short-channel transistor 101S, while FIG. 2 is a simplistic plan view of portions of the long-channel transistor 101L. With reference to FIG. 1, the short-channel transistor 1015 comprises a fin 103A, while the long-channel transistor 101L comprises a fin 103B. In some situations, the fins 103A-B may be collectively referenced using the numeral 103. In the examples depicted herein, each of the transistors 101S, 101L comprise a single fin 103. In practice, the transistors 101S, 101L may comprise any number of fins 103, and the number of fins 103 on each of the transistors 101S, 101L need not be the same, although such a situation may occur in some applications. The fins 103A, 103B may have different axial lengths.

With reference to FIG. 1, the short-channel transistor 101S comprises a simplistically depicted final gate structure 108A, while the long-channel transistor 101L comprises a simplistically depicted final gate structure 108B (the gate structures 108A, 108B may be collectively referenced using the numeral 108). In some applications, the gate structures 108 may be manufactured using replacement gate manufacturing techniques, and the materials of construction for the gate structures 108 may be substantially the same. Of course, the materials of the gate structures 108 for N-type transistor devices may be different from the materials of the gate structures 108 for P-type transistor devices. Also depicted in

FIGS. 1 and 2 are simplistically depicted regions of epi semiconductor material 120 formed in the source/drain regions of the transistors 101S, 101L. Of course, the epi semiconductor material 120 for N-type transistor devices may be different than the epi semiconductor material 120 for P-type transistor devices. A final gate cap that is positioned above each of the final gate structures 108 is not shown in FIGS. 1 and 2.

Still with reference to FIGS. 1 and 2, various cross-sectional views (“X-X” and “Y-Y”) of the product 100 that are depicted in the attached drawings are taken where indicated in FIGS. 1 and 2. The cross-sectional views X-X and Y-Y are taken in the gate length (GL-current transport) direction of the transistors 101S, 101L. More specifically, with reference to FIG. 1, the view X-X is a cross-sectional view taken along the long axis (i.e., the axial length) of the fin 103A of the short-channel transistor 1015. With reference to FIG. 2, the view Y-Y is a cross-sectional view taken along the long axis (i.e., the axial length) of the fin 103B of the long-channel transistor 101L. The drawings herein are not to scale and the relative size of the channel lengths 105, 107 are enlarged so as to facilitate explanation of the inventions disclosed herein. The gate length or current transport direction (GL) of the transistors 101S, 101L as well as the gate width direction (GW) of the transistors 101S, 101L are shown in FIGS. 1 and 2.

In the examples depicted herein, the integrated circuit product 100 will be formed in and above a semiconductor substrate 102. The substrate 102 may have a variety of configurations, such as a semiconductor-on-insulator (SOI) configuration that includes a base semiconductor layer, a buried insulation layer positioned on the base semiconductor layer and an active semiconductor layer positioned on the buried insulation layer. Alternatively, the substrate 102 may have a simple bulk configuration, like that depicted in the attached drawings. The substrate 102 may be made of silicon or it may be made of semiconductor materials other than silicon. Thus, the terms “substrate” or “semiconductor substrate” should be understood to cover all semiconducting materials and all forms of such materials.

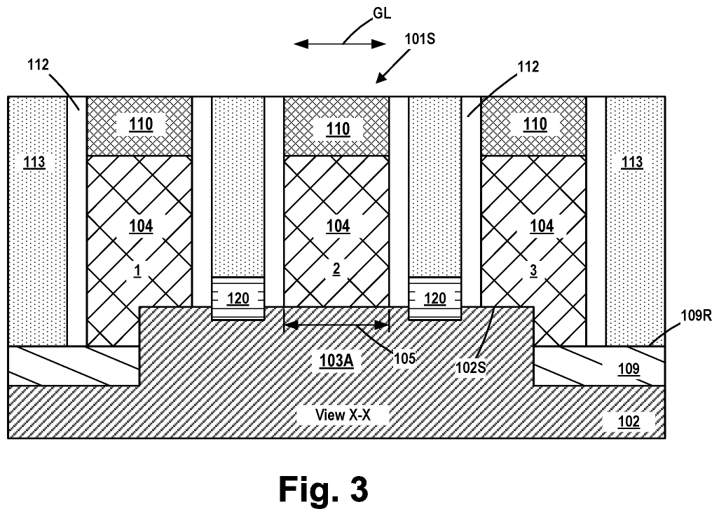

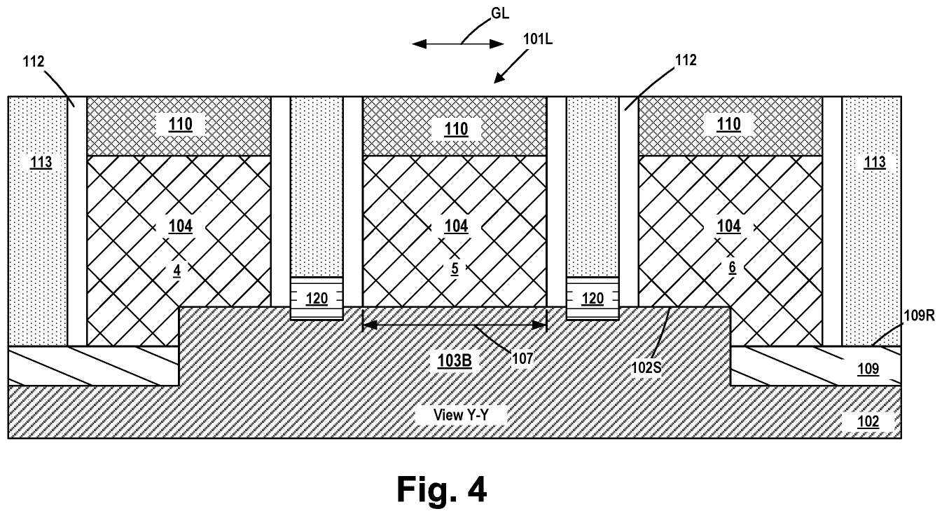

FIGS. 3-4 depict the product 100 after several process operations were performed. More specifically, the fins 103 were formed in the substrate 102 by performing traditional manufacturing techniques. For example, a patterned fin-formation etch mask (not shown—comprised of, for example, a layer of silicon dioxide and a layer of silicon nitride) was formed above the substrate 102. Thereafter, one or more etching processes, e.g., anisotropic etching processes, were performed through the patterned fin-formation etch mask to form a plurality of fin-formation trenches in the substrate 102 and thereby define the plurality of fins 103. The width and height of the fins 103 may vary depending upon the particular application. As noted above, the axial length of the fins 103A, 103B may be different from one another. Additionally, the overall size, shape and configuration of the fin-formation trenches and fins 103 may vary depending on the particular application. The upper surface 102S of the substrate 102 is also depicted in these drawings. In the case where the transistors 1015, 101L are FinFET devices, the upper surface 102S of the substrate 102 is the same as the upper surface of the fins 103. In the case where the transistors 101S, 101L are planar transistor devices, the upper surface 102S would be the substantially planar upper surface of the substrate 102. Next, a recessed layer of insulating material 109 (e.g., silicon dioxide), with a recessed upper surface 109R, was formed between the fins 103 by performing traditional manufacturing techniques, e.g., depositing the insulating material and thereafter performing a recess etching process. Thereafter, at least portions of the patterned fin-formation etch mask were removed.

The final gate structures 108 for the transistors 101S, 101L disclosed herein will be manufactured using one illustrative embodiment of a replacement gate (or “gate-last”) manufacturing technique. Accordingly, still referencing FIGS. 3-4, after the formation of the fins 103, a plurality of sacrificial (or “dummy”) gate structures 104, with a sacrificial gate cap 110 formed there above, were formed across the substrate 102. With reference to FIG. 3, the gate structures 104 have been identified with a number 1-3 for ease of reference. In the completed product 100, the sacrificial gate structure 104 for gate 2 will be replaced with the final gate structure 108A for the short-channel transistor 101S. The gate structures 1 and 3 are considered to be dummy gate structures as it relates to the short-channel transistor 101S.

Similarly, with reference to FIG. 4, the gate structures 104 have been identified with a number 4-6 for ease of reference. In the completed product 100, the sacrificial gate structure 104 for gate 5 will be replaced with the final gate structure 108B for the long-channel transistor 101L. The gate structures 4 and 6 are considered to be dummy gate structures as it relates to the long-channel transistor 101L.

In one illustrative and non-limiting process flow, each of the sacrificial structures 104 comprises a sacrificial gate insulation layer (e.g., silicon dioxide—not separately shown) and a sacrificial gate electrode material (e.g., polysilicon or amorphous silicon—not separately shown). A sacrificial gate cap 110 (e.g., silicon nitride) is positioned above each of the sacrificial gate structures 104. In one illustrative process flow, the sacrificial gate structures 104 (with the gate cap 110 there above) are initially formed as continuous line-type structures that extend across substantially the entire substrate 102, i.e., across both active regions and isolation regions located between active regions. The long continuous line-type sacrificial gate structures 104/gate cap 110 structures may be formed by depositing the materials for the sacrificial gate structures 104 as well as a layer of material for the sacrificial gate caps 110 across the entire substrate 102, forming a patterned gate etch mask (not shown) above the deposited layer of the material for the sacrificial gate caps 110, and performing one or more etching processes through the patterned gate etch mask to remove the exposed portions of sacrificial gate cap material and, thereafter, the exposed portions of the sacrificial gate materials.

Next, still referencing FIGS. 3-4, an illustrative sidewall spacer structure 112 (e.g., silicon nitride, a low-k material (k value of 3.3 or less), etc.) was formed adjacent the long continuous line-type sacrificial gate structures 104 and gate caps 110. The spacer structure 112 may be formed by depositing a conformal layer of spacer material and thereafter performing an anisotropic etching process. In the examples depicted herein, the spacer structure 112 is depicted as a single sidewall spacer. In practice, the spacer structure 112 may be comprised of a plurality of sidewall spacers that may or may not be comprised of different materials.

Various process operations are typically performed with the sacrificial gate structures 104, gate caps 110 and spacer structures 112 in position, e.g., source/drain implantation processes, the formation of epi semiconductor material 120 in the source/drain regions of the transistors 101S, 101L, etc. Then, a conformal contact etch stop layer (not shown, e.g., silicon nitride) may be formed on the product 100 and above the regions of epi semiconductor material 120. At that point, one or more layers of insulating material 113 (e.g., silicon dioxide) was formed across the product 100 so as to over-fill the open spaces between the spacer structures 112. Thereafter, a CMP and/or etch-back process was performed to planarize the upper surface of the layer of insulating material 113 with the upper surface of the sacrificial gate caps 110. In one illustrative example, the sacrificial gate caps 110 may be comprised of silicon nitride, the spacer structures 112 may be comprised of silicon nitride, SiNC, etc. and the insulating material 113 may be silicon dioxide.

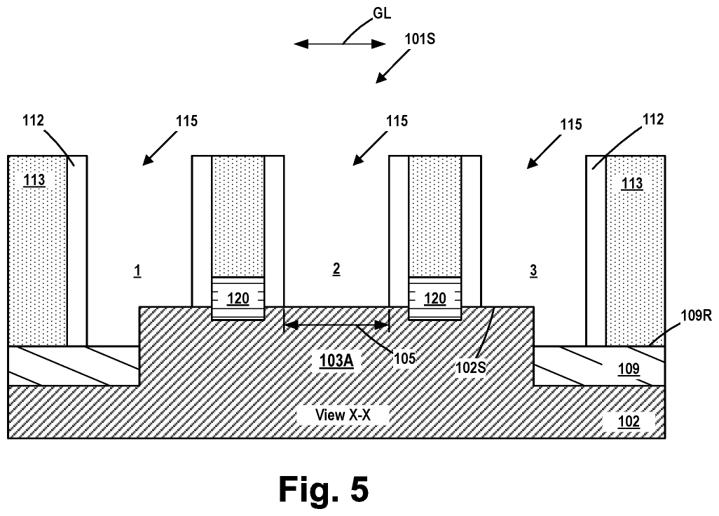

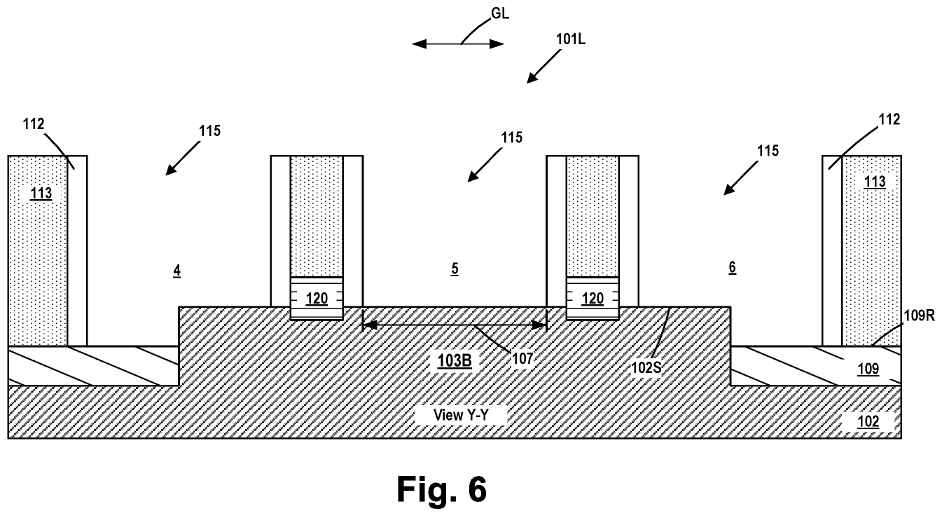

As noted above, the final gate structures 108 for the transistor devices 101S, 101L disclosed herein will be manufactured using one illustrative embodiment of a replacement gate (or “gate-last”) manufacturing technique. Accordingly, FIGS. 5-6, depict the product 100 after several process operations were performed that result in the formation of a plurality of replacement gate cavities 115. More specifically, one or more CMP process operations were performed to remove the sacrificial gate caps 110 and portions of the insulating material 113. This process operation exposes the underlying sacrificial gate structures 104. At that point, at least the sacrificial gate electrode portion of the sacrificial gate structures 104 was removed so as to form the plurality of replacement gate cavities 115 that are located laterally between the spacers 112. In some cases, the entirety of the sacrificial gate structures 104 may be removed so as to expose the upper surface 102S of the substrate 102 within the replacement gate cavities 115.

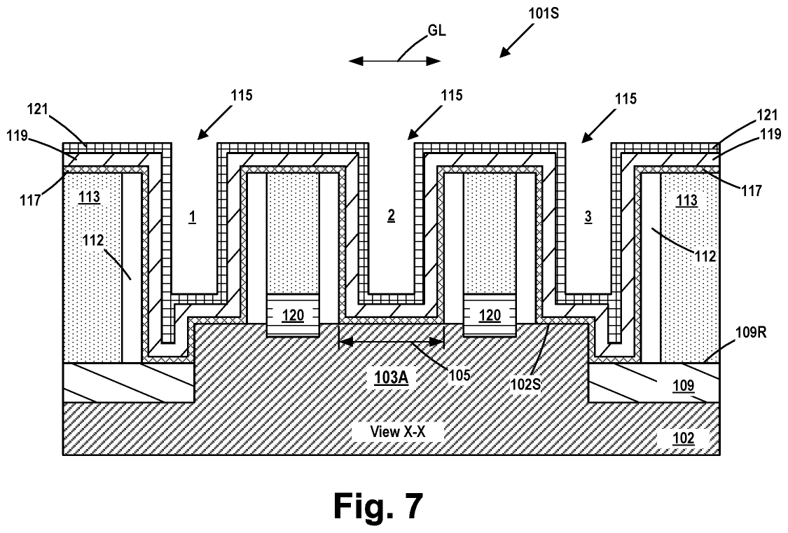

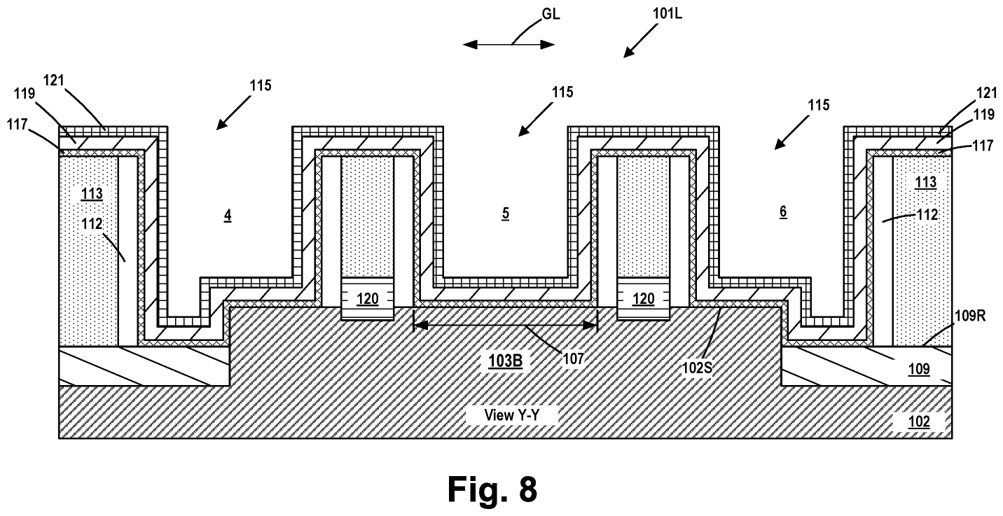

FIGS. 7-8 depict the product 100 after several process operations were performed to form some of the materials of the final gate structures 108 in the replacement gate cavities 115. More specifically, a plurality of conformal deposition processes (e.g., conformal ALD processes) were sequentially performed to form a conformal gate insulation layer 117, a conformal work-function adjusting metal layer 119 (conformal WFM layer 119) and another conformal metal-containing layer 121 across the product 100 and in the replacement gate cavities 115. Of course, as will be understood by those skilled in the art, the number of such conformal layers formed as well as the composition of the conformal layers and the thickness of such layers may vary depending upon the particular application and whether the transistors 101S, 101L are NFET or PFET transistors. Layers of material other than the illustrative conformal layers 117, 119 and 121 may also be present within the replacement gate cavities 115, e.g., in some embodiments, a relatively thin layer of silicon dioxide (not shown) may be formed on or remain on the upper surface 102S of the substrate 102.

In one illustrative example, the gate insulation layer 117 may be comprised of a high-k insulating material (a material having a dielectric constant greater than 10), such as hafnium oxide, etc. The conformal WFM layer 119 may also be comprised of a variety of different materials depending upon whether the transistors 101S, 101L are NFET transistors or PFET transistors. In the illustrative example where the transistors 101S, 101L are NFET transistors, the conformal WFM layer 119 may be comprised of a variety of different materials including, but not limited to, TiAlC, TiN, TiN (with a relatively high amount of N-type dopant), TaN, etc. In the illustrative example where the transistors 101S, 101L are PFET transistors, the conformal WFM layer 119 may be comprised of a variety of different materials including, but not limited to, TaN, TiN, TiON, TiAlC, etc. As noted above, the thickness of the conformal WFM layer 119 may vary depending upon the particular application, e.g., 0.5-6 nm. Additionally, in some applications, two or more conformal WFM layers 119 may be formed within each of the replacement gate cavities 115.

Similarly, the metal-containing layer 121 may also be comprised of a variety of different materials depending upon whether the transistors 101S, 101L are NFET transistors or PFET transistors. In the illustrative example where the transistors 101S, 101L are PFET transistors, the metal-containing layer 121 may be comprised of a variety of different materials including, but not limited to, TiN, W, etc. In the illustrative example where the transistors 101S, 101L are NFET transistors, the metal-containing layer 121 may be comprised of a variety of different materials including, but not limited to, TiN, W, etc. As noted above, the thickness of the metal-containing layer 121 may vary depending upon the particular application, e.g., 1-8 nm.

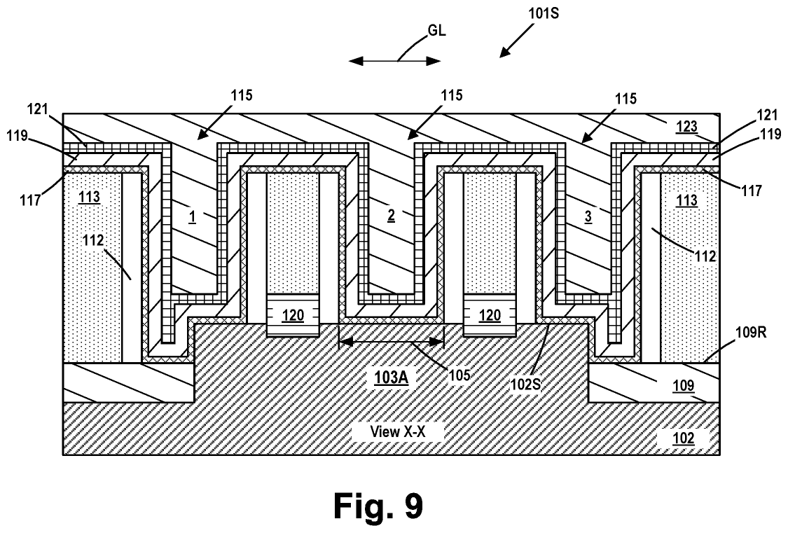

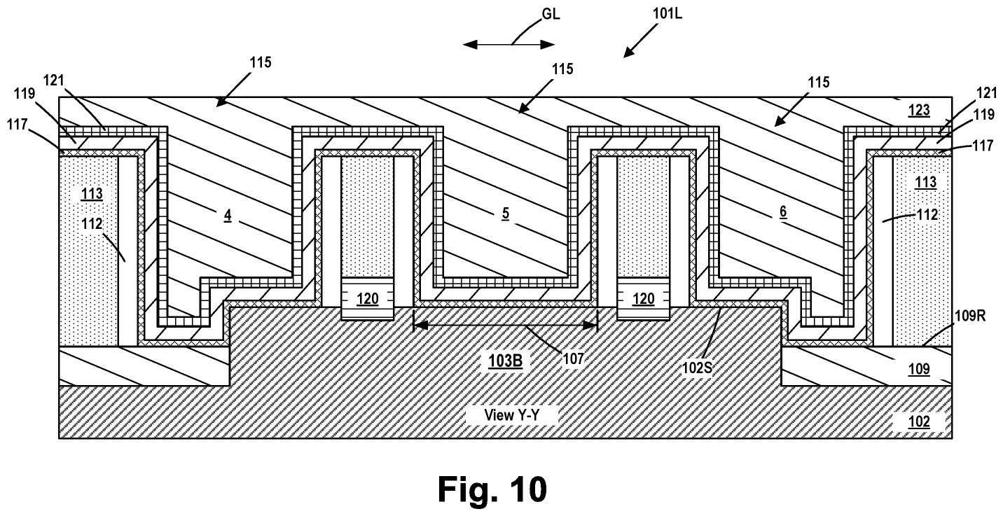

FIGS. 9-10 depict the product 100 after a sacrificial layer of material 123, e.g., a planarization material such as OPL, ODL, BARC, etc., was formed on the product 100 so as to over-fill the replacement gate cavities 115.

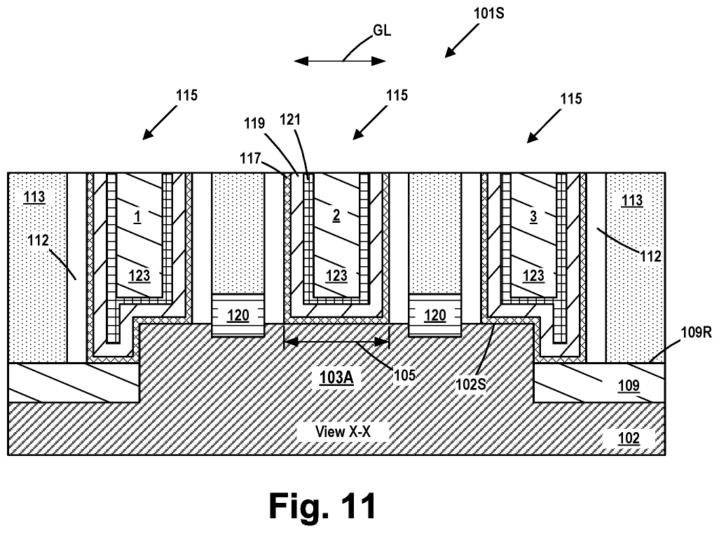

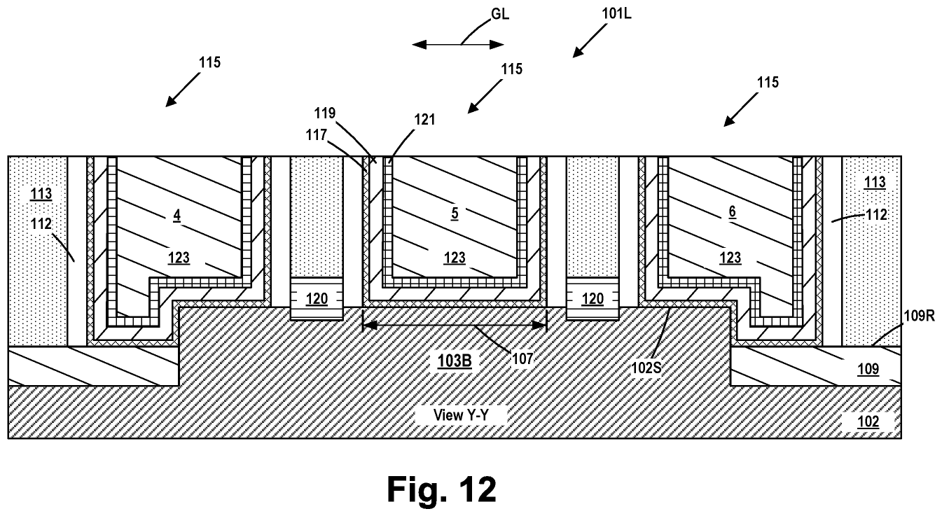

FIGS. 11-12 depict the product 100 after one or more CMP process operations were performed on the product 100 using the insulating material 113 as a polish-stop layer. These operations result in the removal of the portions of the conformal layers of material 117, 119 and 121 and the portion of the sacrificial layer of material 123 positioned outside of the replacement gate cavities 115 and above the upper surface of the insulating material 113.

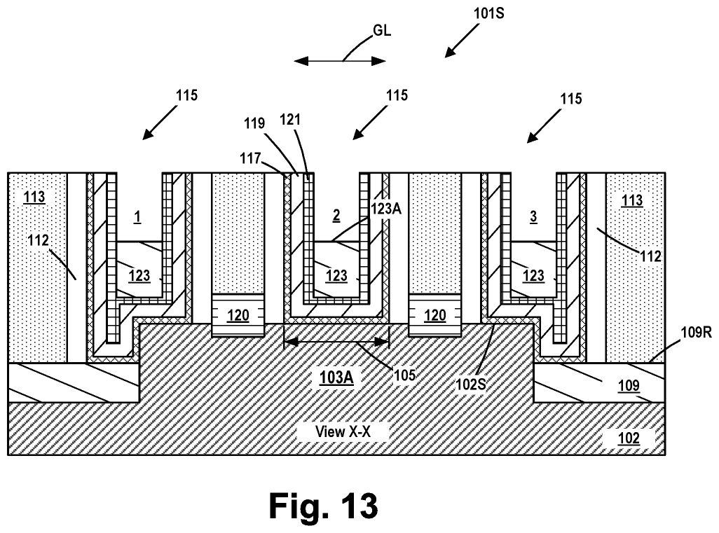

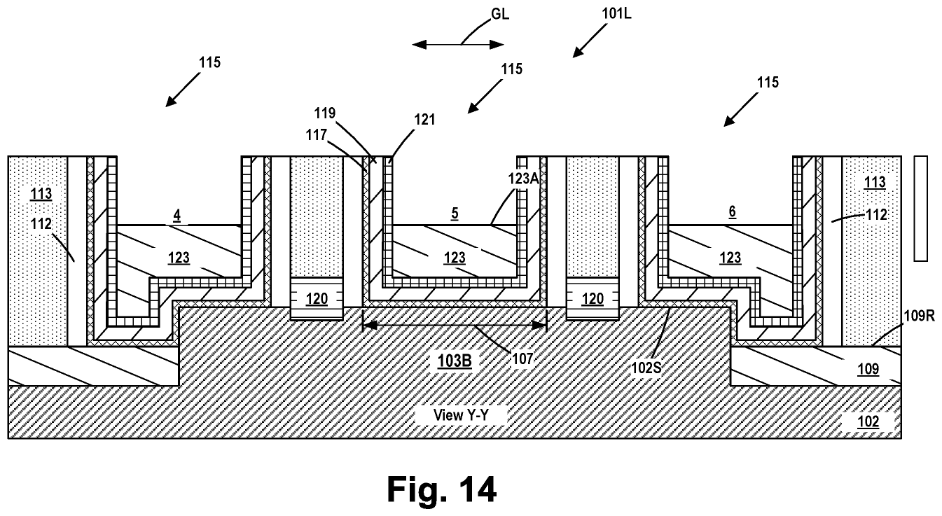

In accordance with one illustrative process flow, FIGS. 13-14 depict the product 100 after a recess etching process was performed on the sacrificial layer of material 123 such that, after this recess etching process is performed, the sacrificial layer of material 123 has a first recessed upper surface 123A in the replacement gate cavities 115 for both the short-channel transistor 101S and the long-channel transistor 101L. As will be described more fully below, the position or level of the first recessed upper surface 123A will approximately set the position or level of an uppermost surface 119A of a short-channel WFM layer 119X for the short-channel transistor 101S. In absolute terms, the position or level of the first recessed upper surface 123A relative to the upper surface 102S of the substrate 102 may vary depending upon the particular application. In one illustrative example, based upon current-day technology, the first recessed upper surface 123A may be positioned about 10-15 nm above the upper surface 102S of the substrate 102. The position of the first recessed upper surface 123A may also be different depending upon whether the transistors 101S, 101L are NFET transistors or PFET transistors.

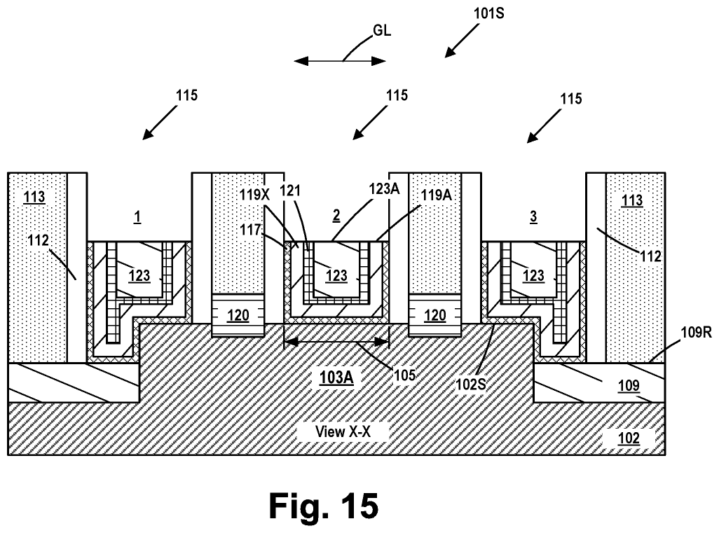

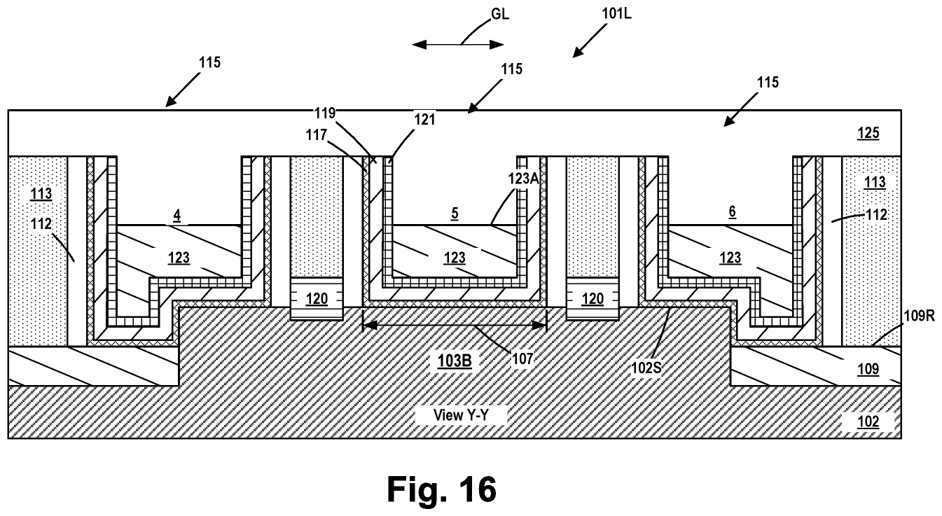

Continuing with this illustrative process flow, FIGS. 15-16 depict the product 100 after several process operations were performed. First, a patterned etch mask 125 (see FIG. 16), e.g., a patterned layer of photoresist, was formed on the product 100 by performing traditional manufacturing techniques. The patterned etch mask 125 covers the long-channel transistor 101L while exposing the short-channel transistor 101S for further processing.

Next, with the patterned etch mask 125 in position, one or more etching processes were performed to remove portions of the conformal layers 117, 119 and 121 on the short-channel transistor 101S that are positioned or located vertically at, near or above the first recessed upper surface 123A of the sacrificial layer of material 123. In the depicted example, the upper surfaces of the conformal layers 117, 119 and 121 are all simplistically depicted as being approximately level with the first recessed upper surface 123A. In a real-world device, the recessing of the conformal layers 117, 119 and 121 may not be so uniform. Importantly, at the conclusion of these process operations, a portion of the original conformal WFM layer 119 becomes the short-channel WFM layer 119X for the short-channel transistor 101S. The short-channel WFM layer 119X has an upper surface 119A that may be positioned at or near the level of the first recessed upper surface 123A of the sacrificial layer of material 123.

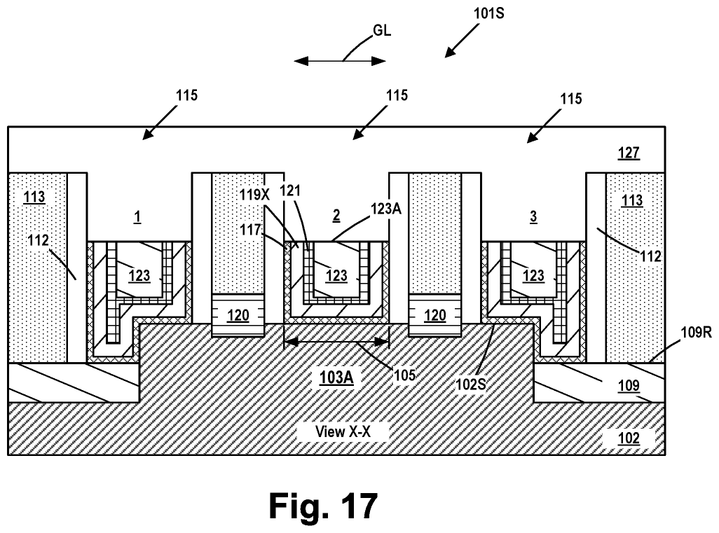

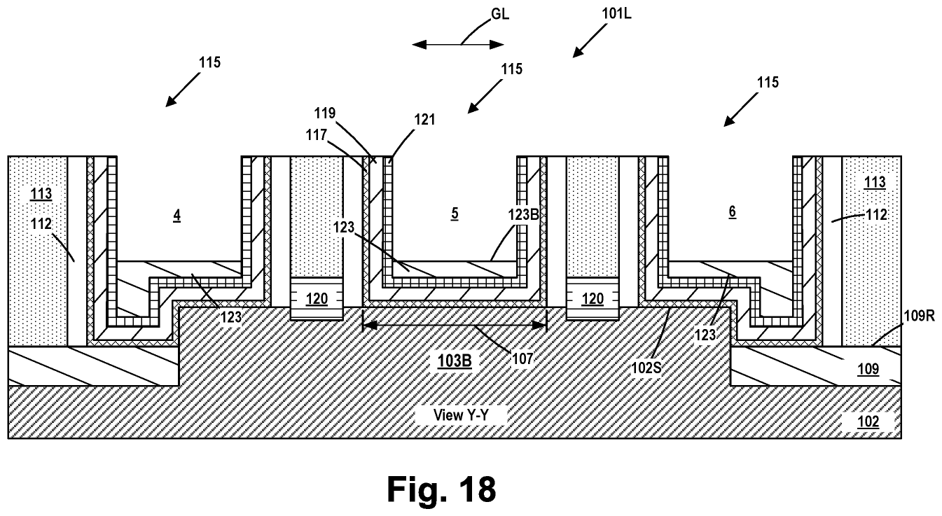

Continuing with this illustrative process flow, FIGS. 17-18 depict the product 100 after several process operations were performed. First, the above-referenced patterned etch mask 125 was removed. Then, another patterned etch mask 127 (see FIG. 17), e.g., a patterned layer of photoresist, was formed on the product 100 by performing traditional manufacturing techniques. The patterned etch mask 127 covers the short-channel transistor 101S while exposing the long-channel transistor 101L for further processing. Next, another recess etching process was performed on the exposed portions of the sacrificial layer of material 123 within the gate cavities 115 for the long-channel transistor 101L. At the conclusion of this second recess etching process, the portion of the sacrificial layer of material 123 on the long-channel transistor 101L has a second recessed upper surface 123B. As will be described more fully below, the position or level of the second recessed upper surface 123B will approximately set the position or level of an uppermost surface 119B of long-channel WFM layer 119Y for the long-channel transistor 101L. In absolute terms, the position or level of the second recessed upper surface 123B relative to the upper surface 102S of the substrate 102 may vary depending upon the particular application. In one illustrative example, based upon current-day technology, the second recessed upper surface 123B may be positioned about 1-10 nm above the upper surface 102S of the substrate 102. At least some portion of the sacrificial material layer 123 will remain in the gate cavity 115 so as to cover the upper surface of the horizontally oriented portion of the metal-containing layer 121. As before, the position of the second recessed upper surface 123B may also be different depending upon whether the transistors 101S, 101L are NFET transistors or PFET transistors. Importantly, in relative terms, the second recessed upper surface 123B is positioned at a level that is intentionally lower than the level of the first recessed upper surface 123A, i.e., the difference in the levels of the surfaces 123A and 123B is not merely the result of manufacturing tolerances.

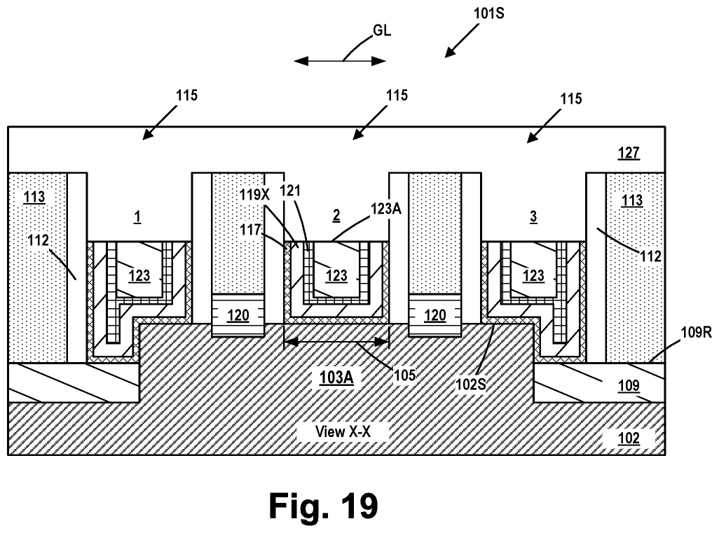

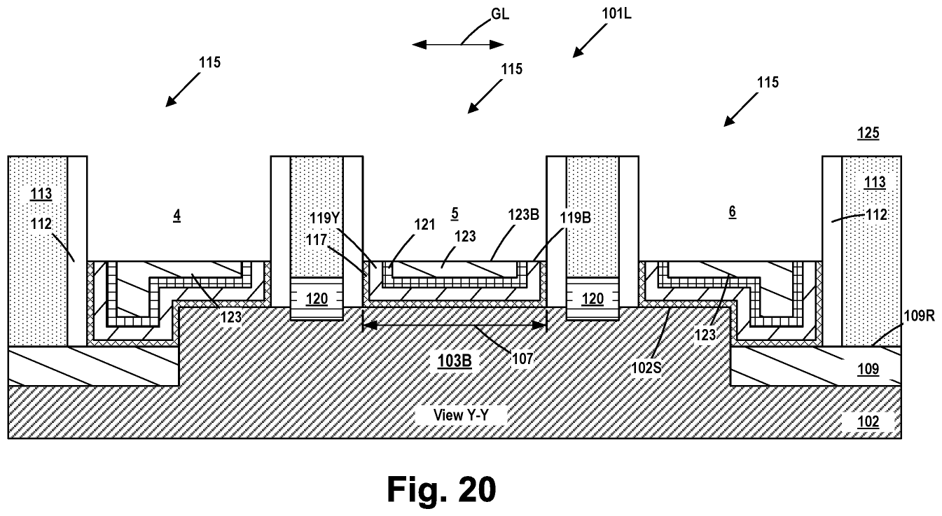

Continuing with this illustrative process flow, FIGS. 19-20 depict the product 100 after several process operations were performed. First, with the patterned etch mask 127 (see FIG. 19) in position, one or more etching processes were performed to remove portions of the conformal layers 117, 119 and 121 on the long-channel transistor 101L that are positioned or located vertically at, near or above the second recessed upper surface 123B of the sacrificial layer of material 123 on the long-channel transistor 101L. As before, in the depicted example, the upper surfaces of the conformal layers 117, 119 and 121 are all simplistically depicted as being approximately level with the second recessed upper surface 123B. In a real-world device, the recessing of the conformal layers 117, 119 and 121 may not be so uniform. Importantly, at the conclusion of these process operations, a portion of the original conformal WFM layer 119 becomes the long-channel WFM layer 119Y for the long-channel transistor 101L. The long-channel WFM layer 119Y has an upper surface 119B that may be positioned or located at or near the level of the second recessed upper surface 123B of the sacrificial layer of material 123.

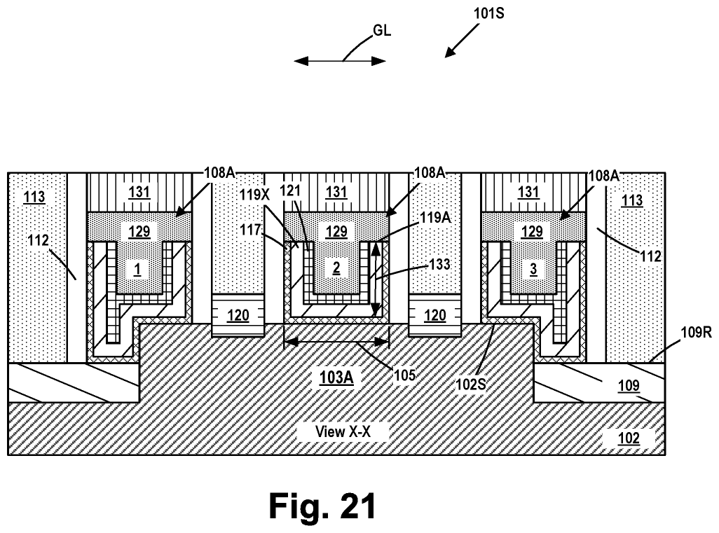

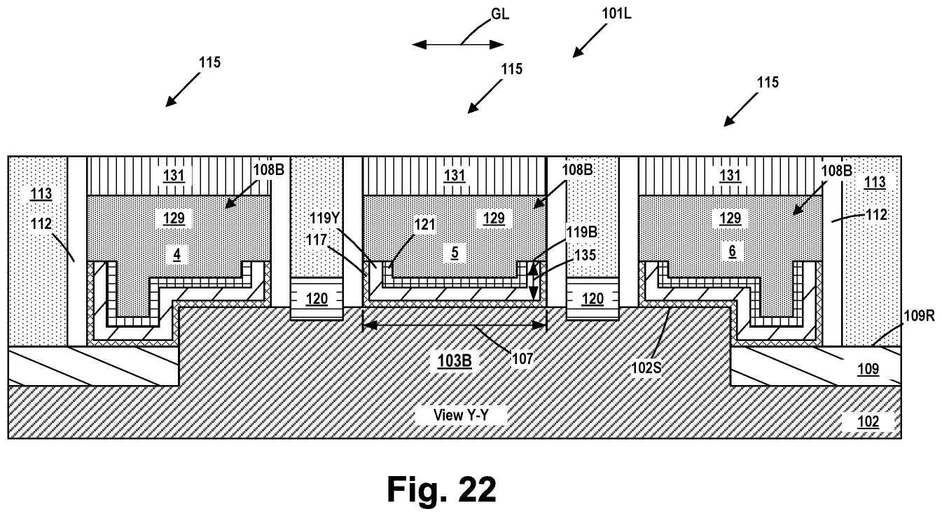

Continuing with this illustrative process flow, FIGS. 21-22 depict the product 100 after several process operations were performed to form the final gate structures 108A, 108B for the short-channel transistor 101S and the long-channel transistor 101L, respectively, as well as final gate caps 131 for the gate structures 108. In one illustrative embodiment, each of the gate structures 108 may comprise a bulk conductive material 129. The bulk conductive material 129 may be comprised of a variety of different materials including, but not limited to, tungsten, cobalt, etc. In one illustrative process flow, a layer of the conductive material 129 may be blanket-deposited across the product 100 so as to over-fill the remaining portions of the replacement gate cavities 115. At that point, a CMP process operation may be performed to remove portions of the layer of conductive material 129 positioned outside of the gate cavities 115 and above the upper surface of the layer of insulating material 113. Then, a recess etching process may be performed to remove some of the vertical thickness of the conductive material 129 within the gate cavities 115 so as to make room for the final gate cap 131 that will be formed above the recessed conductive material 129 within the gate cavities 115. The amount of recessing of the layer of conductive material 129 may vary depending upon the particular application. At that point, a layer of final gate cap material (e.g., silicon nitride) may be deposited across the product 100 so as to over-fill the remaining portions of the replacement gate cavities 115 above the recessed conductive material 129. Then, another CMP process operation may be performed to remove portions of the layer of final gate cap material positioned outside of the gate cavities 115 and above the upper surface of the layer of insulating material 113 so as to thereby form the final gate caps 131 between the spacer structures 112.

With continuing reference to FIGS. 21-22, the upper surface 119A (see FIG. 21) of the short-channel WFM layer 119X for the short-channel transistor 101S is positioned at a level that is higher than the upper surface 119B (see FIG. 22) of the long-channel WFM layer 119Y for the long-channel transistor 101L with respect to a common point of reference such as, for example, the upper surface 102S of the substrate 102. In one illustrative embodiment, the difference in height between the surfaces 119A and 119B may be about 5-15 nm based upon today's technology. In one illustrative example, the minimum difference in height between the surfaces 119A and 119B may be about 5 nm. Assuming the upper surface 102S of the substrate 102 to be a common point of reference, in one illustrative example, the upper surface 119A may be positioned at least about 20 nm above the upper surface 102S, while the upper surface 119B may be positioned less than 10 nm above the upper surface 102S.

Additionally, in one illustrative embodiment, the overall vertical height 133 of the short-channel WFM layer 119X (e.g., the height of the portion of the short-channel WFM layer 119X that contacts the spacer structure 112) may be about 10-25 nm. Similarly, the overall vertical height 135 of the long-channel WFM layer 119Y (e.g., the height of the portion of the long-channel WFM layer 119Y that contacts the spacer structure 112) may be as much as about 10 nm or it may only be about equal to the thickness of the horizontally oriented portions of the long-channel WFM layer 119Y, e.g., the upstanding leg portions of the long-channel WFM layer 119Y may essentially be removed during the processing disclosed above. Stated another way, the vertical height 135 may be the greater of the approximate thickness of the long-channel WFM layer 119Y or 10 nm. However, in some applications, the overall height 135 of the long-channel WFM layer 119Y may be equal to the combined thickness of the long-channel WFM layer 119Y and the thickness of the metal-containing layer 121. Additionally, in one illustrative embodiment, the difference between the overall vertical heights 133, 135 may be about 5-20 nm.

Of course, as will be appreciated by those skilled in the art after a complete reading of the present application, the illustrative process flow described above, i.e., the initial recessing of the sacrificial material layer 123 on both of the transistor devices 101S, 101L, followed by a further recessing of the sacrificial material layer 123 on the long-channel transistor 101L, etc. is but one manner of achieving the desired difference in height between the short-channel WFM layer 119X and the long-channel WFM layer 119Y. In the example depicted herein, the short-channel WFM layer 119X on the short-channel transistor 101S was etched first so as to establish the overall vertical height 133 and, thereafter, the long-channel WFM layer 119Y on the long-channel transistor device 101L was etched to establish the overall vertical height 135. In other process flows, perhaps less efficient and perhaps requiring the formation of additional layers of material (such as an additional layer of sacrificial material 123), the order of etching the original conformal WFM layer 119 to form the short-channel WFM layer 119X and the long-channel WFM layer 119Y may be reversed.

As will be appreciated by those skilled in the art after a complete reading of the present application, the novel method and products disclosed herein may be beneficial to both device manufacturers and the purchasers of IC products as it relates to the manufacture of a final IC product such that it meets or exceeds the originally established product performance specification. In one illustrative example, the formation of the short-channel device 101S and the long-channel device 101L with, respectively, a short-channel WFM layer 119X and a long-channel WFM layer 119Y, may be part of a process flow that effectively provides one means for a product designer to modify the parameters of one or more of the transistors within a given IC product. For example, the formation of the relatively shorter long-channel WFM layer 119Y in the long-channel transistor 101L and the formation of the relatively taller short-channel WFM layer 109X in the short-channel transistor 101S may provide the device designers with a tool to effectively cause a relatively large differential in threshold voltage levels between the short-channel device 101S and the long-channel device 101L. More specifically, with respect to NFET devices, for example, the formation of the taller short-channel WFM layer 109X and the shorter long-channel WFM layer 119Y may cause the threshold voltage of the long-channel device 101L (channel length of at least 60 nm) to be about 60 mV greater than the threshold voltage of the short-channel device 101S. At that point, the threshold voltage characters may be performed (by, for example, a Boolean change to a lithography mask) to effectively change the long-channel device 101L (with the shorter long-channel WFM layer 119Y) from a regular threshold voltage (RVT) device to a low threshold voltage (LVT) device.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. An integrated circuit product, comprising:
a short-channel transistor device and a long-channel transistor device formed above a semiconductor substrate, said semiconductor substrate comprising an upper surface, said short-channel transistor device comprising a first gate length, said long-channel transistor device comprising a second gate length, said second gate length being greater than said first gate length;
a first gate structure for said short-channel transistor device, said first gate structure comprising a short-channel work-function adjusting metal layer (short-channel WFM layer) comprising a first upper surface positioned at a first distance above said upper surface of said semiconductor substrate; and
a second gate structure for said long-channel transistor device, said second gate structure comprising a long-channel work-function adjusting metal layer (long-channel WFM layer) comprising a second upper surface positioned at a second distance above said upper surface of said semiconductor substrate, wherein said first distance is greater than said second distance.

2. The integrated circuit product of claim 1, wherein said first distance is greater than said second distance by at least 5 nm.

3. The integrated circuit product of claim 2, wherein said first gate length is 20 nm or less and said second gate length is greater than 20 nm, and wherein said short-channel transistor device and said long-channel transistor device are N-type FinFET transistor devices.

4. The integrated circuit product of claim 1, wherein said short-channel WFM layer and said long-channel WFM layer comprise a same material.

5. The integrated circuit product of claim 1, wherein said short-channel WFM layer comprises at least one layer of material and wherein said long-channel WFM layer comprises at least one layer of material.

6. The integrated circuit product of claim 1, wherein said first gate structure and said second gate structure further comprise a high-k gate insulation layer and wherein both said short-channel WFM layer and said long-channel WFM layer comprise tungsten.

7. The integrated circuit product of claim 1, wherein said first distance is equal to about 10-25 nm and wherein said second distance is equal to the greater of an approximate thickness of said long-channel WFM layer or 10 nm.

8. An integrated circuit product, comprising:
a short-channel transistor device and a long-channel transistor device formed above a semiconductor substrate, said semiconductor substrate comprising an upper surface, said short-channel transistor device comprising a first gate length, said long-channel transistor device comprising a second gate length, said second gate length being greater than said first gate length;
a first gate structure for said short-channel transistor device, said first gate structure comprising a short-channel work-function adjusting metal layer (short-channel WFM layer) comprising a first overall vertical height; and
a second gate structure for said long-channel transistor device, said second gate structure comprising a long-channel work-function adjusting metal layer (long-channel WFM layer) comprising a second overall vertical height, wherein said short-channel WFM layer and said long-channel WFM layer comprise a same material and wherein a difference between said first overall vertical height and said second overall vertical height is at least about 5-20 nm.

9. The integrated circuit product of claim 8, wherein said short-channel WFM layer comprises a first upper surface and said long-channel WFM layer comprises a second upper surface, said first upper surface being positioned at a first distance above said upper surface of said semiconductor substrate and said second upper surface being positioned at a second distance above said upper surface of said semiconductor substrate, wherein said first distance is greater than said second distance.

10. The integrated circuit product of claim 9, wherein said first distance is greater than said second distance by at least 5 nm.

11. The integrated circuit product of claim 9, wherein said first distance is equal to about 10-25 nm and wherein said second distance is equal to the greater of an approximate thickness of said long-channel WFM layer or 10 nm.

12. The integrated circuit product of claim 8, wherein said first gate structure and said second gate structure further comprise a high-k gate insulation layer and wherein both said short-channel WFM layer and said long-channel WFM layer comprise tungsten.

13. A method of forming an integrated circuit product, comprising:
forming a first sacrificial gate structure for a short-channel transistor device;
forming a second sacrificial gate structure for a long-channel transistor device;
removing said first and second sacrificial gate structures to form first and second replacement gate cavities, respectively, for said short-channel transistor device and said long-channel transistor device;
forming a conformal work-function adjusting metal layer (conformal WFM layer) in said first and second replacement gate cavities; and
performing at least one process operation to remove portions of said conformal WFM layer from within said first and said second replacement gate cavities to form a short-channel WFM layer for a first final gate structure of said short-channel transistor device positioned within said first replacement gate cavity and a long-channel WFM layer for a second final gate structure for said long-channel transistor device positioned within said second replacement gate cavity, wherein a first upper surface of said short-channel WFM layer is positioned at a first distance above an upper surface of said semiconductor substrate and wherein a second upper surface of said long-channel WFM layer is positioned at a second distance above said upper surface of said semiconductor substrate, wherein said first distance is greater than said second distance.

14. The method of claim 13, wherein performing said at least one process operation comprises:
forming a first patterned etch mask, said first patterned etch mask exposing said short-channel transistor device while covering said long-channel transistor device;
with said first patterned etch mask in position, performing at least one first etching process to remove portions of said conformal WFM layer within said first replacement gate cavity so as to form said short-channel WFM layer for said short-channel transistor device;
removing said first patterned etch mask;
forming a second patterned etch mask, said second patterned etch mask exposing said long-channel transistor device while covering said short-channel transistor device;
with said second patterned etch mask in position, performing at least one second etching process to remove portions of said conformal WFM layer within said second replacement gate cavity so as to form said long-channel WFM layer; and
removing said second patterned etch mask.

15. The method of claim 13, wherein performing said at least one process operation comprises:
forming a sacrificial material layer in both said first and second replacement gate cavities;
performing a first recess etching process on said sacrificial material layer so as to form a first recessed sacrificial material layer in both said first and second replacement gate cavities, said first recessed sacrificial material layer comprising a first recessed upper surface positioned at a first distance above said upper surface of said semiconductor substrate;
forming a first patterned etch mask, said first patterned etch mask exposing said short-channel transistor device while covering said long-channel transistor device;
with said first patterned etch mask in position, performing at least one first etching process to remove portions of said conformal WFM layer within said first replacement gate cavity so as to form said short-channel WFM layer for said short-channel transistor device;
removing said first patterned etch mask;
forming a second patterned etch mask, said second patterned etch mask exposing said long-channel transistor device while covering said short-channel transistor device, said second patterned etch mask exposing said first recessed sacrificial material layer positioned within said second replacement gate cavity;
with said second patterned etch mask in position, performing a second recess etching process on said first recessed sacrificial material layer in said second replacement gate cavity so as to form a second recessed sacrificial material layer in said second replacement gate cavity, said second recessed sacrificial material layer comprising a second recessed upper surface positioned at a second distance above said upper surface of said semiconductor substrate, wherein said first distance is greater than said second distance;
with said second patterned etch mask in position, performing at least one second etching process to remove portions of said conformal WFM layer within said second replacement gate cavity so as to form said long-channel WFM layer;
removing said second patterned etch mask; and
removing said first recessed sacrificial material layer within said first replacement gate cavity and said second recessed sacrificial material layer within said second replacement gate cavity.

16. The method of claim 13, further comprising, forming additional conductive material in said first replacement gate cavity above said short-channel WFM layer and in said second replacement gate cavity above said long-channel WFM layer.

17. The method of claim 13, wherein performing said least one process operation comprises performing said at least one process operation so as to form said short-channel WFM layer prior to forming said long-channel WFM layer.

18. The method of claim 13, wherein performing said at least one process operation comprises:
forming first and second portions of a sacrificial material layer in said first and second replacement gate cavities, respectively, said first and second portions of said sacrificial material layer being positioned above a portion of said conformal WFM layer within each of said first and second replacement gate cavities, respectively, said first and second portions of said sacrificial material layer having first and second upper surfaces, respectively, that are positioned at first and second distances, respectively, above said upper surface of said semiconductor substrate, wherein said first distance is greater than said second distance;
with said first portion of said sacrificial material in position within said first replacement gate cavity, performing a first etching process on said conformal WFM layer to form said short-channel WFM layer; and
with said second portion of said sacrificial material in position within said second replacement gate cavity, performing a second etching process on said conformal WFM layer to form said long-channel WFM layer.

19. The method of claim 18, wherein said first distance is at least 5 nm greater than said second distance.
